(19) United States
(12) Patent Application Publication
(10) Pub. No.: US 2004/0120124 A1
(43) Pub. Date: Jun. 24, 2004

(54) Structure and method for positively locating components

(76) Inventor: Patrick Cauwels, South Beloit, IL (US)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/322,844

(22) Filed: Dec. 18, 2002

(51) Int. Cl. H05K 7/20

(52) U.S. Cl. 361/752

(57) ABSTRACT

An apparatus and method of positively locating a plate (14) within a housing (12) includes a first boss (24) and a second boss (36), each boss including petals (26, 38) that are expandable in the radial direction. A plate (14) with two clearance holes (47, 49) is disposed in the housing (12) such that the two bosses (24, 36) engage the two holes (47, 49). A fastener (52) is placed in each of the first and second bosses (24, 36), thereby expanding the petals (26, 38) radially and locating the plate (14) with respect to the X and Y direction and rotationally. The method and apparatus improves the interchangeability between various plates and housings.

### TECHNICAL FIELD

The disclosure is generally related to a method and apparatus to locate objects during assembly, and more particularly to a method and apparatus to locate a printed circuit board and its components during assembly.

### BACKGROUND

Utilization of a printed circuit board (or “PCB”) is the standard method of constructing compact, highly efficient portions of circuits in electrical devices. As is well known in the art, a printed circuit board is constructed of a substrate onto which electrically conductive material terminating in pins is deposited to mimic what in previous designs had been wiring. Connectors must be attached to the substrate by interfacing with the pins to complete the circuits. The circuit boards are preferably accurately and repeatably located and secured within a housing to maintain a high degree of interchangeability and to assure completion of assembly to a success level of at least six sigma.

Presently, two methods of assembly are typically used to ensure accurate location and assembly of the circuit board with respect to the housing. In the first method, the housing employs two or more bosses disposed within the housing and the PCB employs two or more clearance holes cut in the circuit board and sized to be the diameter of the bosses plus a clearance amount to ensure that the board will fit on the bosses. The PCB is placed in the housing such that each boss is disposed within a respective hole. The first boss locates the circuit board with respect to the X and Y directions, and the second boss restricts rotation of the circuit board around the first boss. In this case, the converse is also true In the second method, the housing uses two bosses, while the circuit board employs a clearance hole and a slot. In this method, the boss and the clearance hole restrict the board in the X and the Y directions, and the boss disposed inside the slot restricts the board rotationally about the first boss.

The two previously described methods required considerable relative clearance between the bosses and the clearance holes in order to guarantee a high degree of interchangeability between PCB's and housings. The clearance holes must be made large enough such that if the dimensions of the bosses are at one extreme of their allowable tolerance, and the clearance holes are at the other extreme, the PCB must still be able to be assembled to the housing. Sources of variation in the manufacture of the parts of the first method include the diameter of the bosses, the center to center distance between the bosses, the diameter of the clearance holes, and the center to center distance between the clearance holes. Even with generous averaging of tolerances, to achieve a six-sigma success rate, it is not unusual, given a highly interchangeable design, to have a possible shift of the assembled PCB and housing of approximately ±0.50 mm. Stated another way, to ensure that each PCB and housing will be successfully assembled together, enough clearance must be built into the PCB holes to ensure that they mate with the housing bosses that it is impossible to know exactly where the PCB will be located with respect to the housing to an accuracy of better than 1 mm.

In the two-pin, hole and slot configuration, some improvement is made by eliminating center-to-center variation between the holes and between the bosses, though not skew, so the sources of variation still include the diameter of the locating boss, the diameter of the locating hole within the PCB, the diameter of the aligning boss, and the diameter of the aligning slot in the PCB. Here, it is not unusual to have an assembly shift of approximately ±0.37 mm. However, a problem with a slot is that more of the substrate must be removed, and there is less room for components to be deposited on the PCB.

Therefore, clearances that aid in interchangeability translate into assembly shift that can cause sources of potential interference for other close proximity features in a system. This causes significant variation in position between components on the PCB and other nearby features on the housing such as ribs, interior wall surfaces, etc. Further, this assembly shift translates to every component on the PCB; for small envelope and critical designs, this level of assembly shift is significant, manifesting itself through internal interferences, display skew, and connector misalignments.

### BRIEF DESCRIPTION OF THE DRAWINGS

FIG. 1 is an isometric view of a PCB housing constructed in accordance with the teachings of this disclosure.

FIG. 2 is an isometric view of a first locator of the housing of FIG. 1.

FIG. 3 is an isometric view of a second locator of the housing of FIG. 1.

FIG. 4 is a section view of the housing, partially assembled, and taken along line 4-4 of FIG. 1.

FIG. 5 is a detail view of the second locator of FIG. 4.

FIG. 6 is a detail view of the first locator of FIG. 4.

FIG. 7 is an isometric view of a cellular telephone with a PCB housing constructed in accordance with the teachings of this disclosure.

FIG. 8 is an elevational view of the PCB located within the housing of the cellular telephone.

FIG. 9 is a detail view of the first and second bosses of the cellular telephone of FIG. 8.

FIG. 10 is an alternate embodiment of a cover for a PCB housing constructed in accordance with the teachings of this disclosure.

While the disclosure is susceptible to various modifications and alternative constructions, certain illustrative embodiments thereof have been shown in the drawings and will be described below in detail. It should be understood, however, that there is no intention to limit the disclosure to the specific forms disclosed, but on the contrary, the intention is to cover all modifications, alternative constructions, and the equivalents falling within the spirit and scope of the invention as defined by the appended claims.

### DETAILED DESCRIPTION OF THE PREFERRED EMBODIMENTS

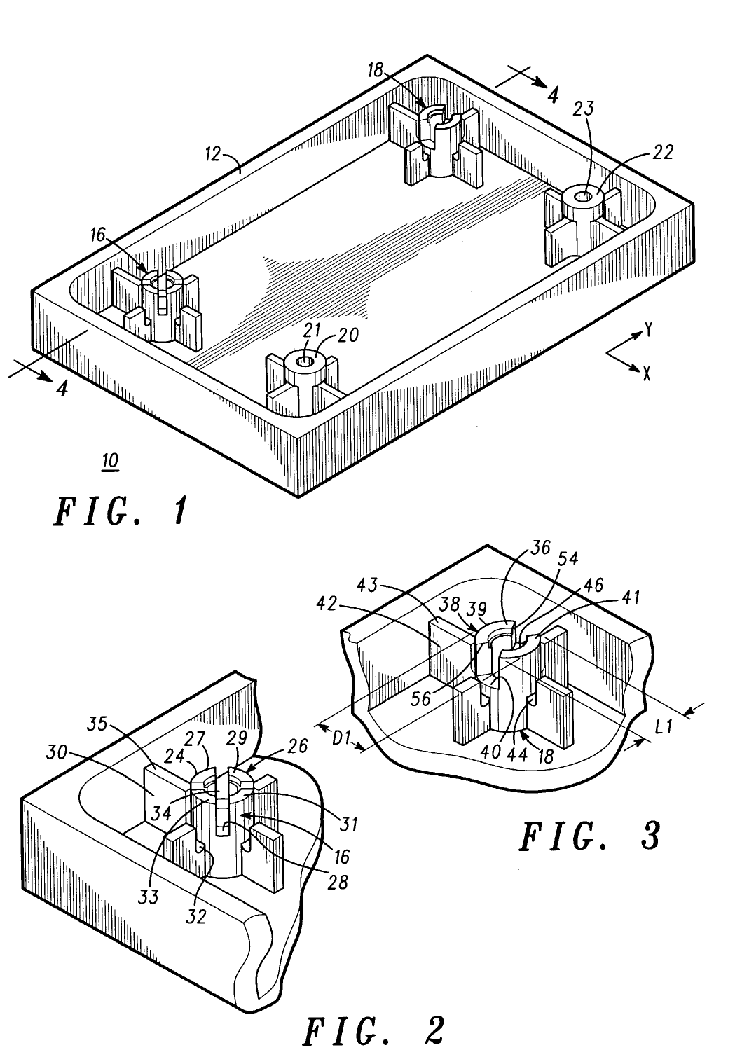

Referring now to the drawings, in particular FIG. 1 and FIG. 4, a device for positively locating components is generally referred to by reference numeral 10. The device 10 includes a housing 12 that is used to accommodate an element, in this example a printed circuit board 14. Although a printed circuit board 14 is shown and described, the method and apparatus disclosed herein can be used to locate and secure any plate-like element. As used herein, it will be understood that a plate or a plate-like element can be any element that is relatively thin compared to its length and/or width. The device 10 further includes a first locator 16 and a second locator 18, used to locate and fasten the exemplary printed circuit board 14 in the housing 12. The device 10 further includes at least one vertical support 20, which aids in maintaining the exemplary circuit board 14 at a predetermined elevation. In the disclosed example, the device 10 includes a first support 20 and a second support 22 with center holes 21 and 23.

A line extending from the center of the first locator 16 to the center of the second locator 18 defines a direction Y, or north direction. A line extending from the center of the first locator 16 and perpendicular to the direction Y defines a direction X, or east direction. Reference to directions such as north and east are used herein only to facilitate understanding of the disclosure by the reader. It will be readily understood that these references in no way limit the scope of the application.

Referring now to FIG. 2, the first locator 16 includes a generally cylindrical first boss 24. The first boss 24 is divided into petals 26, in this example four petals 27, 29, 31, and 33. However, it is contemplated that the first boss 24 can be divided into fewer petals, or as many petals as the size of the first boss 24 will accommodate while still retaining sufficient radial strength, as discussed infra. The petals 26 are separated by channels 28. The depth of the channels 28 defines the height of the petals 26.

The first locator 16 can include a rib 30 disposed adjacent the first boss 24. The rib 30 provides a surface 35 on which the printed circuit board 14 rests. In the present example, four ribs are shown, however, fewer or more could be employed to support the printed circuit board 14. Each rib 30 also includes a relief 32. The relief 32 is a cut-away portion of the rib 30 adjacent the first boss 24. The channels 28 and the reliefs 32 allow the petals 26 to expand radially. The first boss 24 further includes a cylindrical hole 34 at its radial center.

Referring now to FIG. 3, the second locator 18 also includes a second boss 36, which is generally cylindrical. The second boss 36 is divided into petals 38, in this example petals 39, 41. The petals 38 are divided by grooves 40. The grooves 40 effectively displace material at the north and south ends of the second boss 36 such that the effective distance L1 across the petal 38 is less than the diameter D1 of the second boss 36. In other words, in this example, the diameter of the second boss 36 in the X direction is greater than in the Y direction.

The second locator 18 can include a rib 42 disposed adjacent the second boss 36. The rib 42 provides a surface 43 on which the printed circuit board 14 rests. In the present example, four ribs are shown, however, fewer or more could be employed to support the printed circuit board 14. Each rib 42 also includes a relief 44. The relief 44 is a cut-away portion of the rib 42 adjacent the second boss 36. The grooves 40 and the relief 44 allows the petals 38 to expand radially. The second boss 36 further includes a cylindrical hole 46 at its radial center.

FIGS. 4-6 depict the device 10 in a partially assembled condition. The printed circuit board 14 is disposed in the housing 12. The printed circuit board 14 further includes holes 47, 49 with inner surfaces 51, 53 such that the first locator 16 and the second locator 18 are matingly engaged with the holes 47, 49, respectively. Disposed on top of the housing 12 is a cover 50. The cover 50 includes through holes 55 that are substantially coaxial with the cylindrical holes 34 and 46 of the first boss 24 and the second boss 36.

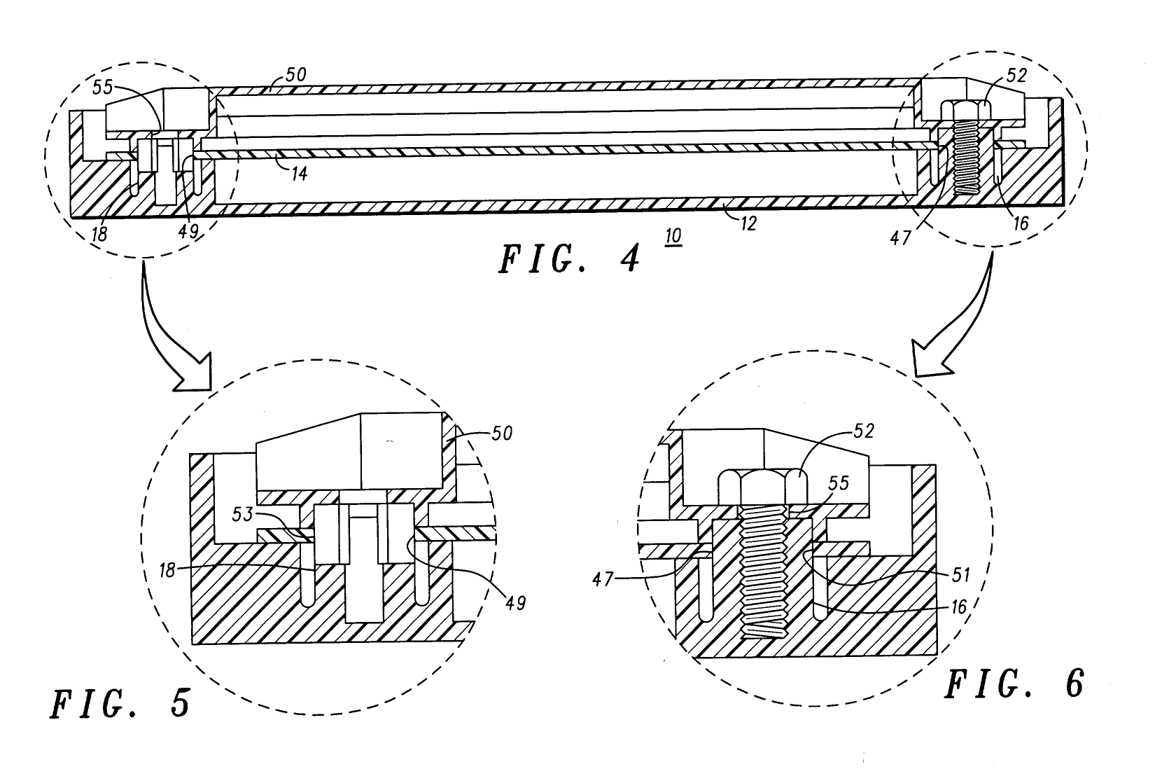

With regard to the first locator 16, shown in particular in FIG. 6, a fastener 52 is shown disposed within the cylindrical hole 34 of the first boss 24. The fastener 52 is depicted as a threaded fastener such as a screw, however, other fasteners known in the art such as rivets, nails, bolts, or press fit pins could be used. Fastener 52 secures the cover 50 to the housing 12, thus securing the printed circuit board 14 in between. In this example, the cylindrical hole 34 is not tapped prior to receiving the fastener 52. Thus, the fastener 52 cuts into the inner surface and removes material from the cylindrical hole 34 as it is introduced into the first boss 24, creating a secure fit. Although not shown in FIGS. 4 or 5, a fastener is used in a similar manner in the second locator 18.

In accordance with the disclosure, a housing 12 with first and second locators 16 and 18 is provided. A printed circuit board 14 with holes 47, 49 is disposed in the housing 12 such that the locators 16 and 18 are matingly engaged with the holes 47, 49. A cover 50 is then disposed on the housing 12. The cover 50, the printed circuit board 14 and the housing 12 are secured together by the fasteners 52.

The structure and process of using the device 10 aids in locating the printed circuit board 14 within the housing 12. The channels 28 divide the first boss 24 into a series of individual flexible petals 26 that can flex in the radial direction. The fastener 52 being introduced into the cylindrical hole 34 of the first boss 24 acts as a wedge and forces the petals 26 to expand radially outward. This presses the petals 26 against the inner surface 51 of the hole 47 of the printed circuit board 14, thereby positively locating the center of the hole 47 of the printed circuit board 14 to be substantially coaxial with the center of the cylindrical hole 34 of the first locator 16. It is also contemplated that the housing 12 and/or the petals 26 could be a combination of flexible and rigid materials.

The ribs 30 support the printed circuit board 14 within the housing 12. The ribs 30 include a relief 32 such that the petals 26 of the first boss 24 are free to expand radially. The petals 26 are shown to expand in the X direction and in the Y direction, however, the petals 26 could be disposed on the first boss 24 such that they expand in directions other than the X and Y directions.

Thus, the printed circuit board 14 can be repeatably and securely located with respect to the housing while still employing a clearance hole 47 that is adequately larger in diameter than the first boss 24, thus aiding in assembly. This is in contrast to prior designs in which a greater clearance was required between the boss and the holes of the printed circuit board to ensure fit during assembly and no structure or method was used to securely and repeatably locate the PCB with respect to the housing. The clearance hole 47 has a diameter that limits expansion of the first boss 24 occurring by the introduction of the fastener 52 into the holes 34 and 46, and provides hoop strength to the assembly. Thus, the first boss 24 locates the printed circuit board 14 with respect to the X direction and the Y direction. However, the printed circuit board 14 must still be located and secured rotationally about the first boss 24.

Next, introducing a fastener 52 into the cylindrical hole 46 of the second boss 36 expands the petals 38 radially, and in this example, in the X direction. The hole 49 in the printed circuit board 14 can be either a slot or a clearance hole, as disclosed in the prior art. The expansion of the petals 38 against the inner surface 53 hole 49 positively locates and secures the printed circuit board 14 and permits no rotation of the printed circuit board 14 about the first locator 16 and thus no movement with respect to the housing 12. The expansion of the petals 38 further maintains the center of the second boss 36 substantially coaxial with the center of the hole 49.

By including the groove 40 in the second boss 36, no material is disposed at a north position 54 or a south position 56. Because the length of the petals L1 is less than the diameter D1 of the boss, center-to-center variation between the first and second bosses 24, 36 in combination with the center-to-center variation between the holes 47, 49 in the printed circuit board can be better accommodated. In other words, since the length L1 of the second boss 36 is smaller than its diameter D1, interchangeability between PCB's and housings is improved because assembly is possible in situations of greater center to center variation between the aforementioned features than if the length F1 was equal to the diameter D1 of the second boss 36.

The disclosed device 10 exploits the flexibility of the petals 26, 38 by using a fastener 52 as both a securing element and a wedge to expand the first and second bosses 24,36 to the full size of the clearance holes 47, 49. This eliminates assembly clearances, and achieves positive, repeatable location. The device 10 further employs the printed circuit board 14 to provide a reaction force on the first and second bosses 24, 36 and the fastener 52 for aid in retention of the PCB 14.

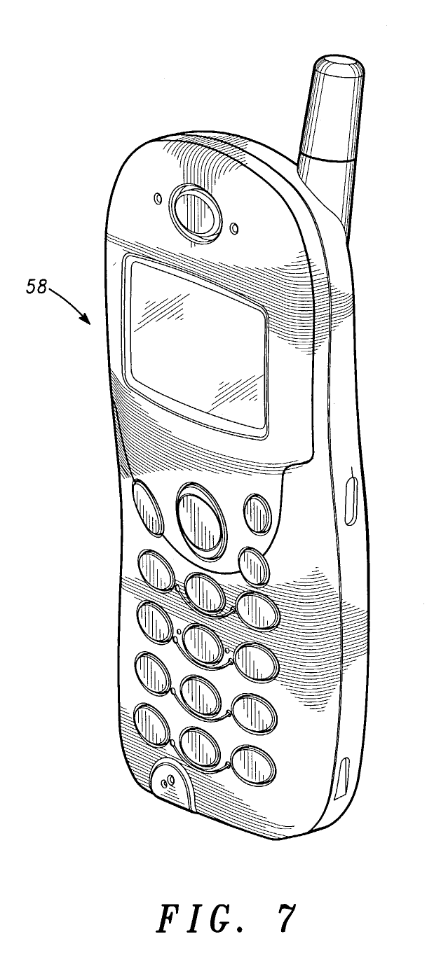

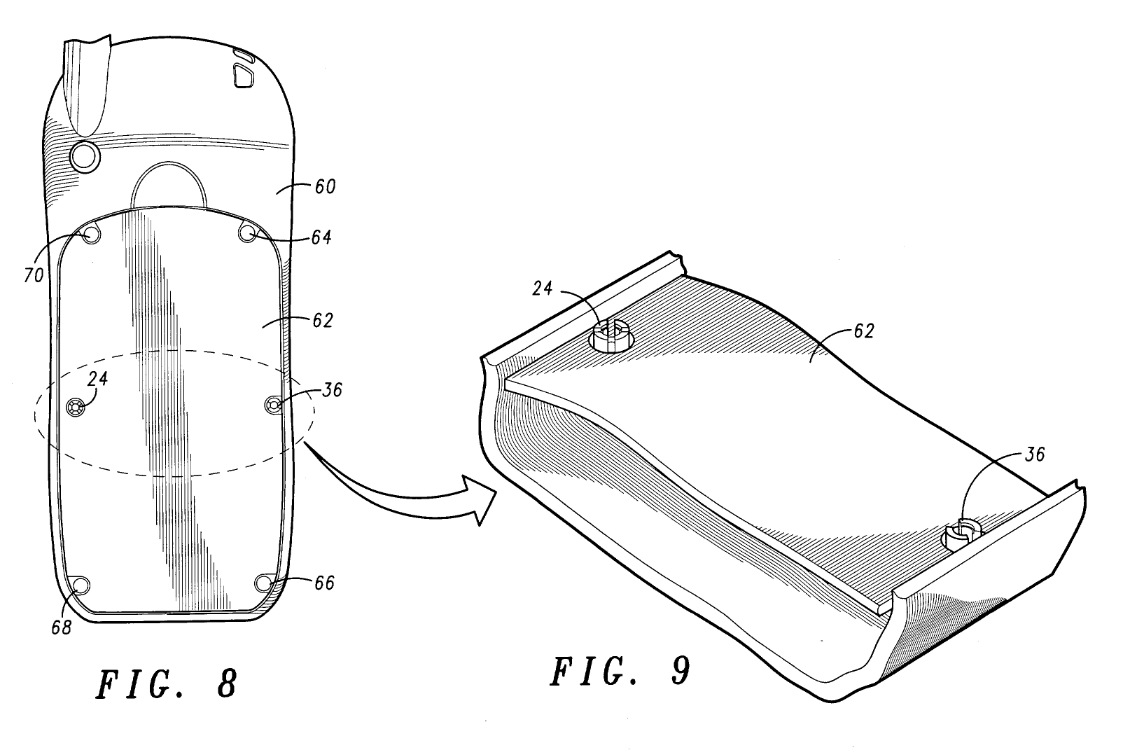

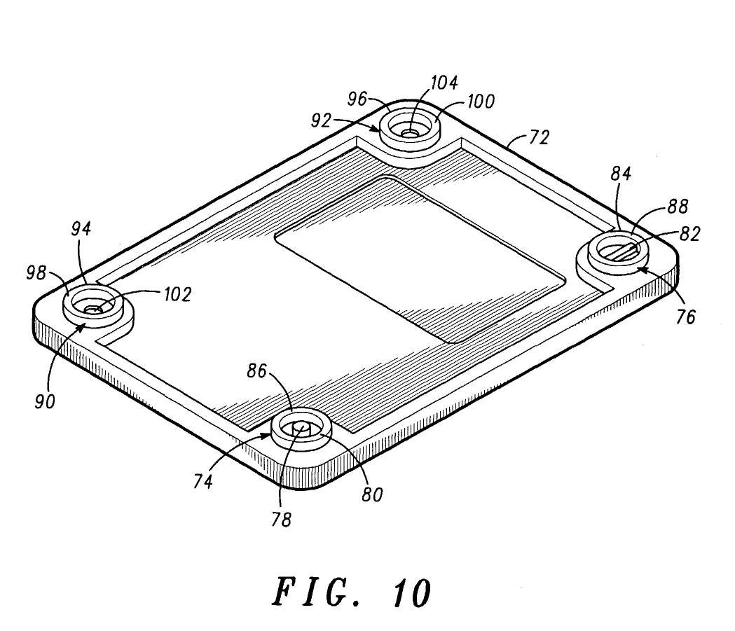

FIGS. 7, 8, and 9 show an application particularly suited for the use of the apparatus and method disclosed herein. FIG. 7 shows a cellular telephone 58, that is well known in the art, which has been constructed and assembled in accordance with the teachings of this disclosure. FIG. 8 shows a housing 60 for the cellular telephone 58 and a printed circuit board 62 located in the housing 60. In this example, the housing 60 includes the first boss 24 and the second boss 36, and further includes four more bosses 64, 66, 68 and 70 which in this embodiment are simply locating pins in the shape of rigid cylinders, well known in the art, that do not expand to locate the printed circuit board 62. In alternative embodiments, the bosses 64, 66, 68 and/or 70 could also be expandable using petals as disclosed herein such as either the first boss 24 or the second boss 36.

In a further embodiment, shown in FIG. 10, fasteners 52 are not used to control the flexure of the petals. FIG. 10 shows an example of a cover 72 which not only encases the printed circuit board 14, but also expands the petals 26 and 38. The cover 72 includes a primary expander 74 and a secondary expander 76. The primary expander 74 includes a pin 78 and an annular ring 80. The secondary expander 76 includes a key 82 and an annular ring 84.

In practice, the printed circuit board 14 is placed within the housing 12, as shown in, for example, FIGS. 1 and 4. The cover 72 is placed on the housing 12 with the pin 78 of the primary expander 74 being located in the cylindrical hole 34 of the first boss 24, and the key 82 of the secondary expander 76 being located in the cylindrical hole 46 of the second boss 36. The pin 78 and the key 82 expand the petals 26 and 38 of the first boss 24 and the second boss 36, as described above. The pin 78 and the key 82 both may be tapered to ease the entry of the pin 78 and the key 82 into the first and second bosses 24 and 36 and improve the expansion of the petals 26 and 38.

The annular rings 80 and 84 each have a surface 86 and 88. The surfaces 86 and 88 of the annular rings 80 and 84 bear down directly on the printed circuit board 14. The annular rings 80 and 84 control the depth of engagement of the pin 78 and the key 82 within the cylindrical holes 34 and 46.

The cover 72 may further include retainers 90 and 92. The retainers 90 and 92 also include annular rings 94 and 96 with surfaces 98 and 100 which may bear down on either the housing 12 or the printed circuit board 14. The retainers 90 and 92 also include holes 102 and 104. When the cover 72 is placed on the housing 12, the holes 102 and 104 are substantially coaxial with the center holes 21 and 23 of the first and second supports 20 and 22. Fasteners such as screws or bolts (not shown) may be inserted through the holes 102 and 104 and into the center holes 21 and 23 to fasten the cover 72 to the housing 12 and retain the printed circuit board 14 therebetween. Further, the housing 12 and the cover 72 may be snap fit using structure that is well known in the art.

From the foregoing, one of ordinary skill in the art will appreciate that the present disclosure sets forth a method and apparatus for accurately and repeatably locating a printed circuit board within a housing. It further increases the interchangeability of printed circuit boards within a housing and increases the assembly success rate. Although the embodiments disclosed herein are particularly well suited for use with a cellular telephone, persons of ordinary skill in the art will readily appreciate that the teachings of this disclosure are in no way limited to cellular telephones. On the contrary, persons of ordinary skill in the art will readily appreciate that the teachings of this disclosure can be employed with any number of devices, including, but not limited to, machine tools, automotive applications, precision gauges, fixtures, pagers, personal digital assistants (PDA), computers, etc. Further, the number of locators can be increased, or even decreased, such as employing a locating pin and one expandable boss. As such, the teachings of this disclosure shall not be considered to be limited to the specific examples disclosed herein, but to include all applications within the spirit and scope of the invention.

What is claimed is:

1. An apparatus, comprising:
a housing;
a first boss disposed within the housing, the first boss including a plurality of petals and a center hole; and
a second boss disposed within the housing, the second boss including a plurality of petals and a center hole.

2. The apparatus of claim 1, further comprising a plate located on the housing and including a first and second clearance hole, the first boss and the second boss disposed within the first and second clearance holes.

3. The apparatus of claim 2, wherein the plate is a printed circuit board.

4. The apparatus of claim 2, further comprising a first fastener disposed within the center hole of the first boss.

5. The apparatus of claim 4, wherein at least one of the petals of the first boss are adapted to expand radially in response to the first fastener being disposed within the center hole of the first boss.

6. The apparatus of claim 5, wherein the petals of the first boss are adapted to expand against the inner surface of the first clearance hole of the plate, whereby the center of the first clearance hole is located substantially coaxial with the center of the hole of the first boss.

7. The apparatus of claim 4, further comprising a second fastener disposed within the center hole of the second boss.

8. The apparatus of claim 7, wherein at least one of the petals of the second boss are adapted to expand radially in response to the second fastener being disposed within the center hole of the second boss.

9. The apparatus of claim 8, wherein the petals of the second boss are adapted to expand against the inner surface of the second clearance hole of the plate, whereby the center of the second clearance hole is located substantially coaxial with the center of the hole of the second boss.

10. The apparatus of claim 1, the first boss including a plurality of petals disposed radially and equally about the center of the hole of the first boss.

11. The apparatus of claim 10, wherein the first boss includes four petals.

12. The apparatus of claim 1, the second boss including a plurality of petals disposed radially and equally about the center of the hole of the second boss, wherein an axis defined by connecting the first boss to the second boss defines a north direction.

13. The apparatus of claim 12, wherein the second boss includes two petals.

14. The apparatus of claim 13, wherein the two petals of the second boss are disposed on the east and west side of the boss and are adapted to be expandable in the east and west direction.

15. The apparatus of claim 14, wherein the two petals of the second boss are separated by grooves on the north side and the south side.

16. The apparatus of claim 15, wherein a length of the second boss in the north-south direction is less than a width of the second boss in the east-west direction.

17. The apparatus of claim 2, further including a cover disposed on the housing with the plate in between the cover and the housing.

18. The apparatus of claim 17, the cover further including holes that are substantially coaxial with the center holes of the first boss and the second boss.

19. The apparatus of claim 18 further including fasteners disposed through the holes of the cover and in the center holes of the first and second boss.

20. The apparatus of claim 19, wherein the petals of the first and second boss are adapted to be radially expandable in response to the disposition of the fasteners within the center holes of the first and second boss.

21. The apparatus of claim 20, wherein the plate is adapted to be located by the radial expansion of the petals of the first and second boss.

22. The apparatus of claim 17, the cover further including a primary expander and a secondary expander.

23. The apparatus of claim 22, the primary expander including an annular ring and a pin disposed inside the annular ring.

24. The apparatus of claim 23, the secondary expander including an annular ring and a key disposed inside the annular ring.

25. The apparatus of claim 24, further including the pin being disposed in the center hole of the first boss, and the key disposed in the center hole of the second boss.

26. The apparatus of claim 25, wherein pin is tapered and the key is tapered.

27. The apparatus of claim 25, wherein the petals of the first boss are adapted to radially expand in response to the pin being disposed in the center hole of the first boss, and the petals of the second boss are adapted to radially expand in response to the key being disposed in the center hole of the second boss.

28. A method of locating a plate within a housing, the housing including a first boss and a second boss, the first and second bosses each including radially expandable petals and a center hole, the method comprising;
disposing a plate in the housing, the plate including first and second clearance holes, the first boss being disposed in the first clearance hole, the second boss being disposed within the second clearance hole;
introducing a first fastener into the center hole of the first boss, thereby expanding the petals of the first boss radially; and
introducing a second fastener into the center hole of the second boss, thereby expanding the petals of the second boss radially.

29. The method of claim 28, wherein the first fastener and the second fastener are threaded screws.

30. The method of claim 29, wherein the center hole of the first boss and the center hole of the second boss are smooth, such that the first fastener and the second fastener cut into the sides of the center holes as they are inserted.

31. The method of claim 28, wherein a Y direction is defined by an axis connecting the first boss with the second boss, and an X direction is defined as perpendicular to the Y direction, and the first boss locates the plate with respect to the X and Y direction.

32. The method of claim 31, wherein the second boss locates the plate with respect to its rotational position about the first boss.

33. A cellular telephone comprising:
a housing;
a generally cylindrical first boss disposed within the housing, the first boss including a plurality of flexible petals and a center hole, the center hole being substantially coaxial with the generally cylindrical first boss;
a generally cylindrical second boss disposed within the housing, the second boss including a plurality of flexible petals and a center hole, the center hole being substantially coaxial with the generally cylindrical second boss;
a plate including a first clearance hole and a second clearance hole, the plate being disposed in the housing, the first boss being disposed in the first clearance hole, the second boss being disposed in the second clearance hole;
a first fastener being disposed within the center hole of the first boss, wherein the petals of the first boss are forced radially outward into contact with the first clearance hole of the plate; and
a second fastener being disposed within the center hole of the second boss, wherein the petals of the second boss are forced radially outward into contact with the second clearance hole of the plate.

34. The cellular telephone of claim 33, wherein the plate is a printed circuit board.

35. The cellular telephone of claim 33, wherein the second clearance hole of the plate is a slot.

36. An apparatus to locate and secure a plate within a housing, the apparatus comprising:
a housing;
a locating pin;
a generally cylindrical second boss including a first and a second flexible petal separated by a first and a second channel, and a center hole substantially coaxial with the boss;
an axis defined by a line connecting the pin to the boss and defining a north direction;
the first and second petals located on the east and west side of the boss, respectively, the diameter of the boss being greater in the east-west direction than the north-south direction;
a plate with a first clearance hole and a second clearance hole located within the housing, the locating pin being disposed within the first clearance hole, and the boss being disposed within the second clearance hole; and
a fastener disposed within the center hole of the second boss, whereby the first and second petals of the second boss are forced in an east and west direction against the clearance hole of the plate, thereby aligning the plate rotationally about the pin.

37. A cellular telephone comprising:
a housing; and
a first boss disposed in the housing and including a plurality of radially expandable flexible petals and a center hole.

38. The cellular telephone of claim 37, the housing further including a pin.

39. The cellular telephone of claim 37, the housing further including a second boss, the boss including a plurality of flexible petals and a center hole.

40. The cellular telephone of claim 39, the housing further including a plurality of locating pins.
